(19) United States
(12) Patent Application Publication
(10) Pub. No.: US 2022/0094826 A1
(43) Pub. Date: Mar. 24, 2022

(54) CAMERA MODULE FOR A MOTOR VEHICLE, AND METHOD FOR MANUFACTURING A CAMERA MODULE

(71) Applicant: Robert Bosch GmbH, Stuttgart (DE)

(72) Inventor: Andreas Moehrle, Stuttgart (DE)

(21) Appl. No.: 17/445,882

(22) Filed: Aug. 25, 2021

(30) Foreign Application Priority Data
Sep. 23, 2020 (DE) 102020211869.8

(51) Int. Cl. H04N 5/225; G02B 7/02; B60R 11/04

(52) U.S. Cl. CPC H04N 5/2254; H04N 5/2253; B60R 11/04; G02B 7/02

(57) ABSTRACT

A camera module for a motor vehicle. The camera module includes a lens system housing; a lens system accommodated in the interior of the lens system housing; at least one circuit board on which an image sensor is situated; multiple strip conductors which are situated on an outer side of the lens system housing and designed to electrically connect at least one electrical consumer to the circuit board. In the process, the at least one electrical consumer is situated in the interior of the lens system housing.

### CROSS REFERENCE

The present application claims the benefit under 35 U.S.C. § 119 of German Patent Application No. DE 102020211869.8 filed on Sep. 23, 2020, which is expressly incorporated herein by reference in its entirety.

### FIELD

The present invention relates to a camera module for a motor vehicle and to a method for manufacturing a camera module.

### BACKGROUND INFORMATION

German Patent Application No. DE 2013 205 161 A1 describes an imager module for a camera, which at least includes: a circuit carrier, in particular, as a MID circuit carrier, a lens system mount preferably designed as part of the circuit carrier, a lens system accommodated in the lens system mount, and an image sensor mounted and contacted on the circuit carrier. In the process, at least one heating element for heating the lens system mount is provided in the lens system accommodating area, in particular, as a heating strip conductor.

### SUMMARY

The present invention is directed to a camera module for a motor vehicle, including a lens system housing, a lens system accommodated in the interior of the lens system housing, at least one circuit board on which an image sensor is situated, multiple strip conductors which are situated on an outer side of the lens system housing and designed to electrically connect at least one electrical consumer to the circuit board.

According to an example embodiment of the present invention, the at least one electrical consumer is situated in the interior of the lens system housing.

The electrical consumer may, for example, be designed as a lens heater, a lens system heater, an autofocus function, an active image stabilization unit, a variable aperture, an illumination unit or as a combination thereof.

An advantage of the present invention is that a direct electrical contacting of an electrical consumer situated in the interior of the lens system housing with the circuit board is easily implementable. The configuration of the strip conductors along the lens system housing is geometrically flexible. In addition, the manufacturing process may be drastically simplified. The contacting may thus also be handled in a simple and (fully) automated manner within a large-scale manufacture. In addition, different materials may be used for the lens system housing. The lens system housing may, for example, be made of metal or of plastic. Another advantage is that the camera module may have a compact design. This results, in particular, in advantages for the installation in a motor vehicle.

In one advantageous embodiment of the present invention, it is provided that the lens system housing includes at least one passage, at least one contact pin being situated in the passage, the at least one contact pin being designed to electrically connect at least one of the multiple strip conductors to the at least one electrical consumer. The contact pins may also be referred to as pin contacts in the process. The advantage of this embodiment is that the electrical contacting of the electrical consumer situated in the interior of the lens system housing with the circuit board is thus considerably simplified.

In one particularly advantageous embodiment of the present invention, it is provided that the passage is situated in an area of the lens system housing which faces away from the circuit board. The advantage of this embodiment is that a current conduction from the circuit board via the lens system housing to the portion of the lens system which faces away from the circuit board is simplified. The electrical consumer may preferably be situated in this portion of the lens system.

In one further particularly advantageous embodiment of the present invention, it is provided that the at least one contact pin is situated in the passage in such a way that it protrudes on the side of the passage facing the circuit board. The advantage of this embodiment is that the contacting of the strip conductors with the at least one contact pin is considerably simplified.

In one further advantageous embodiment of the present invention, it is provided that at least one electrically conductive connecting unit is situated on the circuit board, which is electrically connectable to at least one of the multiple strip conductors in such a way that at least one electrical current path is formable. The advantage of this embodiment is that a reliable electrical contacting of the circuit board with the multiple strip conductors is implementable.

In one further advantageous embodiment of the present invention, it is provided that the electrically conductive connecting unit is designed to be elastic. The electrically conductive connecting unit is, in particular, designed as a spring element. The spring element may have a very low stiffness. The advantage of this embodiment is that a reliable electrical contacting of the circuit board with the multiple strip conductors may also be ensured, for example, after the lens system has been aligned with respect to the circuit board or with respect to the image sensor.

In one further advantageous embodiment of the present invention, it is provided that the multiple strip conductors are designed as MID strip conductors. MID denotes molded interconnect devices, which are injection-molded circuit carriers. The strip conductors are, in particular, situatable on the outer side of the lens system housing with the aid of multi-component injection molding or with the aid of hot embossing. The advantage of this embodiment is that the strip conductors are easier to manufacture. In particular, the manufacturing process may be drastically simplified. Situating the strip conductors on the outer side of the lens system housing may also be handled in a simple and (fully) automated manner within a large-scale manufacture. The manufacture in the injection molding process or with the aid of hot embossing results in a greater design freedom of the strip conductors. In addition, the camera module may have a compact design.

In one further advantageous embodiment of the present invention, it is provided that the electrical consumer is situated at at least one of the optical lenses of the lens system. The advantage of this embodiment is that the electrical consumer is able to act directly on the optical lens. If the electrical consumer is designed as a heating element, for example, it may heat the optical lens directly. As an autofocus function, active image stabilization unit and/or variable aperture, the electrical consumer may have direct influence on the optical mode of action of the optical lens.

In one further advantageous embodiment of the present invention, it is provided that the electrical consumer is designed as a heating element. An advantage of this embodiment is that at least one area of the interior of the lens system housing may be heated. In this way, it is possible, in particular, to prevent one of the optical lenses of the lens system from fogging with moisture. In this way, a disruption of the image recording may be prevented. It is possible to ensure correct image recordings with the aid of the camera module. This is, in particular, of great importance when the camera module is used in an at least semi-autonomously drivable motor vehicle.

In one preferred embodiment of the present invention, it is provided that the electrical consumer is situated at a lens situated furthermost from the circuit board. In the process, the lens situated furthermost from the circuit board may be understood as the optical lens which faces the field of vision of the camera. This has, in particular, advantages when the electrical consumer is designed as a heating element. In this way, the optical lens facing the field of vision may advantageously be prevented from fogging with moisture.

The present invention is furthermore directed to a method for manufacturing a camera module, the method including providing at least one circuit board on which an image sensor is situated; providing a lens system housing; situating a lens system in the interior of the lens system housing; situating an electrical consumer in the interior of the lens system housing; situating multiple strip conductors on an outer side of the lens system housing; and electrically connecting the at least one electrical consumer to the circuit board.

In one example embodiment of the present invention, it is provided that the method includes the further steps of providing at least one passage in the lens system housing, situating at least one contact pin in the passage; and electrically connecting at least one of the multiple strip conductors to the at least one electrical consumer with the aid of the contact pin.

In one further example embodiment of the present invention, it is provided that the method includes one further step of situating the strip conductors on the outer side of the lens system housing with the aid of multi-component injection molding or with the aid of hot embossing.

It shall be understood that the above-mentioned features and those still to be described hereafter may be used not only in the particular described combination, but also in other combinations, or alone, without departing from the scope of the present invention.

### BRIEF DESCRIPTION OF THE DRAWINGS

Exemplary embodiments of the present invention are described in greater detail hereafter based on the figures. Identical reference numerals in the figures indicate identical or identically operating elements.

FIG. 1 shows an exemplary embodiment of a camera module in accordance with the present invention.

FIG. 2 shows a side view of the lens system housing in accordance with the present invention.

FIG. 3 shows a top view onto the lens system housing in accordance with an example embodiment of the present invention.

FIG. 4 shows an exemplary embodiment of a method for manufacturing a camera module in accordance with the present invention.

### DETAILED DESCRIPTION EXAMPLE EMBODIMENTS

FIG. 1 shows camera module 100 as an exemplary embodiment. It includes circuit board 101 on which image sensor 102 is situated. The attachment of image sensor 102 on circuit board 101 takes place with the aid of attachment elements 103 in the example shown here. Attachment element 103 may, for example, be designed as a solder spot or as an adhesive bond. Camera module 100 furthermore includes camera housing 104. Circuit board 101 is situated at camera housing 104 in the example. Here, circuit board 101 is attached to camera housing 104 with the aid of elements 105. Elements 105 may, for example, be designed as screws.

Camera module 100 furthermore includes a lens system housing 108. In the process, the lens system housing, in turn, includes an area 108-1 facing away from the circuit board, and an area 108-2 facing the circuit board. Camera housing 104 and lens system housing 108 may be connected to one another with the aid of at least one alignment element 109. The at least one alignment element 109 is situated at area 108-1 of lens system housing 108 in the shown example.

A lens system 113 is accommodated in the interior of lens system housing 108. Lens system 113 may include multiple optical lenses in the process, as is shown in the example, optical lens 113 which is situated furthermost from circuit board 101 being identified in FIG. 1. Furthermore, electrical consumers 112 are also situated in the interior of the lens system housing. Electrical consumers 112 are situated at optical lens 113 in the example shown here. Electrical consumers 112 may advantageously be designed as heating elements.

Multiple strip conductors 110 are situated on the outer side of lens system housing 108, which are designed to electrically connect electrical consumers 112 to circuit board 101. Strip conductors 110 may be designed as MID strip conductors.

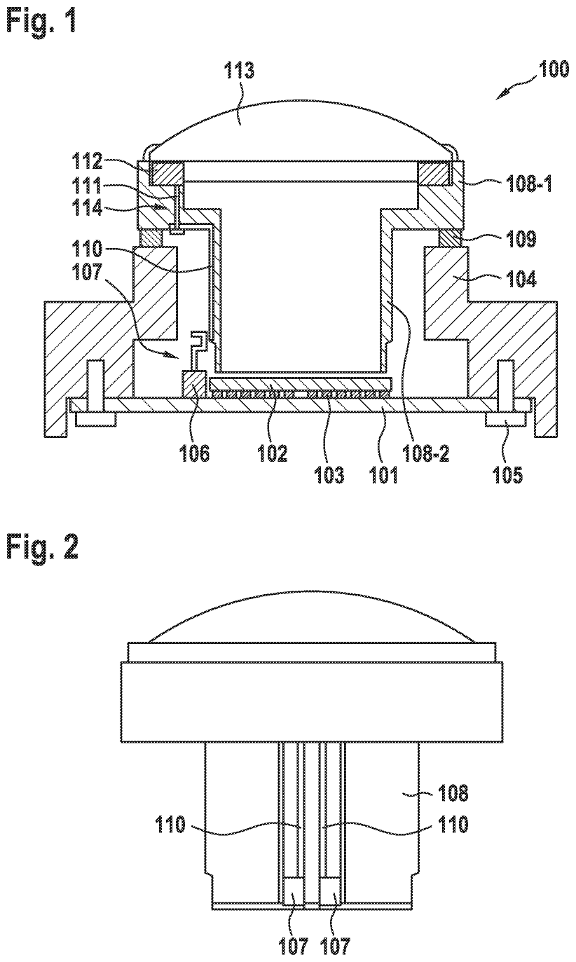

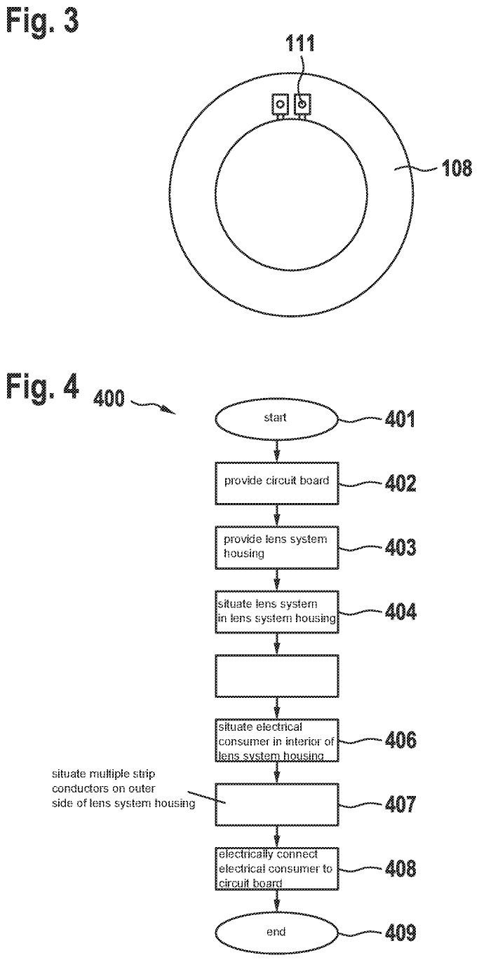

As is shown in FIG. 1, lens system housing 108 may include at least one passage 114. At least one contact pin 111 may be situated in passage 114. Strip conductors 110 may be electrically connected to electrical consumers 112 with the aid of contact pin 111. FIG. 3 shows a top view onto lens system housing 108. The viewing direction in the process is from area 108-2 to area 108-1. Contact pins 111 are apparent in this top view. As is additionally apparent in FIG. 1, contact pin 111 may be situated in passage 114 in such a way that it protrudes on the side of passage 114 facing circuit board 101. It is furthermore apparent in FIG. 1 that an electrical connecting unit 107 is situated on circuit board 101. Electrical connecting unit 107 is electrically connectable to the strip conductors in such a way that at least one electrical current path is formable. Electrical connecting unit 107 may have an elastic design. FIG. 2 shows a side view of lens system housing 108 including strip conductors 110 situated on the outer side of lens system housing 108. As is shown here by way of example, strip conductors 110 are electrically connected to electrical connecting units 107.

FIG. 4 shows an exemplary embodiment of a method for manufacturing a camera module. The method starts in step 401. In step 402, at least one circuit board is provided, on which an image sensor is situated. In step 403, a lens system housing is provided. In step 404, a lens system is situated in the interior of the lens system housing. In step 406, an electrical consumer is situated in the interior of the lens system housing. In step 407, multiple strip conductors are situated on an outer side of the lens system housing. In step 408, the at least one electrical consumer is electrically connected to the circuit board. The method ends in step 409.

The method may include further steps not explicitly shown in FIG. 4. For example, at least one passage may be provided in the lens system housing. At least one contact pin may be situated in the at least one passage. At least one of the multiple strip conductors may be electrically connected to the at least one electrical consumer with the aid of the at least one contact pin.

In one further embodiment of the present invention, it is provided that the strip conductors are situated on the outer side of the lens system housing with the aid of multi-component injection molding or with the aid of hot embossing.

What is claimed is:

1. A camera module for a motor vehicle, comprising:
a lens system housing;
a lens system accommodated in an interior of the lens system housing;
at least one circuit board on which an image sensor is situated;
multiple strip conductors, which are situated on an outer side of the lens system housing and which are designed to electrically connect at least one electrical consumer to the circuit board;
wherein the at least one electrical consumer is situated in the interior of the lens system housing.

2. The camera module as recited in claim 1, wherein the lens system housing includes at least one passage, at least one contact pin being situated in the passage, the contact pin being configured to electrically connect at least one of the multiple strip conductors to the at least one electrical consumer.

3. The camera module as recited in claim 1, wherein at least one electrically conductive connecting unit is situated on the circuit board, which is electrically connectable to at least one of the multiple strip conductors in such a way that at least one electrical current path is formable.

4. The camera module as recited in claim 3, wherein the electrically conductive connecting unit has an elastic design.

5. The camera module as recited in claim 1, wherein the multiple strip conductors are MID strip conductors.

6. The camera module as recited in claim 1, wherein the electrical consumer is situated at at least one of optical lenses of the lens system.

7. The camera module as recited in claim 1, wherein the electrical consumer is a heating element.

8. A method for manufacturing a camera module, the method comprising the following steps:
providing at least one circuit board on which an image sensor is situated;
providing a lens system housing;
situating a lens system in an interior of the lens system housing;
situating an electrical consumer in the interior of the lens system housing;
situating multiple strip conductors on an outer side of the lens system housing; and
electrically connecting the at least one electrical consumer to the circuit board.

9. The method as recited in claim 8, further comprising the following steps:
providing at least one passage in the lens system housing;
situating at least one contact pin in the passage; and
electrically connecting at least one of the multiple strip conductors to the at least one electrical consumer using the contact pin.

10. The method as recited in claim 8, furthermore comprising the following step:
situating the strip conductors on the outer side of the lens system housing using multi-component injection molding or hot embossing.
